(19) United States
(12) Patent Application Publication
(10) Pub. No.: US 2007/0048938 A1
(43) Pub. Date: Mar. 1, 2007

(54) Method of manufacturing MOS transistor with multiple channel structure

(75) Inventors: Eun-jung Yun, Seoul (KR); Sung-young Lee, Yongin-si (KR); Min-sang Kim, Seoul (KR); Sung-min Kim, Incheon Metropolitan City (KR); Yong-lack Choi, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/431,626

(22) Filed: May 10, 2006

(30) Foreign Application Priority Data
Aug. 30, 2005 (KR) 10-2005-0079957

(51) Int. Cl. H01L 21/336

(52) U.S. Cl. 438/257; 438/264

(57) ABSTRACT

A method of manufacturing a MOS transistor with a multiple channel structure prevents damage to and loss of material of a channel region. The method includes: forming a stacked structure including a plurality of first material layers and a plurality of second material layers that have different etching selectivities and are alternately stacked on a semiconductor substrate; forming an active mask on a portion of the stacked structure, the active mask defining an active region; etching regions of the stacked structure to expose sidewalls of the stacked structure; forming a plurality of tunnels by selectively removing the first material layer between the exposed sidewalls of the stacked structure; removing the active mask; and forming a gate electrode on the active region to fill the plurality of tunnels.

### CROSS-REFERENCE TO RELATED PATENT APPLICATION

This application claims priority to of Korean Patent Application No. 10-2005-0079957, filed on Aug. 30, 2005, in the Korean Intellectual Property Office, the disclosure of which is incorporated herein in its entirety by reference.

### BACKGROUND OF THE INVENTION

1. Field of the Invention

The present invention relates to a method of manufacturing a semiconductor device, and more particularly, to a method of manufacturing a metal oxide semiconductor (MOS) transistor with a multiple channel structure.

2. Description of the Related Art

As the integration density of semiconductor devices continues to increase, the size of a MOS transistor (i.e. the channel length and width of the MOS transistor) has been reduced so that more devices can be integrated into a limited area. Although high integration of integrated circuits (IC) can be achieved by reducing the channel length and width of the MOS transistor, this approach is subject to certain disadvantages such as the short channel effect and the narrow width effect caused by drain induced barrier lowering (DIBL), hot carrier effect, punch through, and the like. Consequently, the short channel effect can cause the MOS transistor to operate abnormally, and the threshold voltage of the MOS transistor can be lowered by the narrow width effect.

To prevent the short channel effect and the narrow width effect from occurring, a MOS transistor structure with a three-dimensionally extended channel length and width has been developed. Examples of this transistor configuration include a fin type, a fully DEpleted Lean-channel TrAnsistor (DELTA) type, and a Gate All Around (GAA) type.

In the fin-type MOS transistor, an active region where a channel is formed in a fin structure that extends in a vertical direction relative to the substrate and a gate electrode is formed to cover the top and sidewalls of the fin-type active region. This configuration provides the effect of extending the channel length or width of the transistor. A MOS transistor with this fin structure is disclosed in U.S. Pat. No. 6,413,802, incorporated herein by reference.

The DELTA-type MOS transistor has a protruding channel region. Additionally, a gate electrode is formed-on the surface of the protruding channel region in order to provide the effect of extending the channel length or width of the transistor. The DELTA-type MOS transistor is disclosed in U.S. Pat. No. 4,996,574.

The GAA type is more advanced than the fin-type and the DELTA-type, and is formed with a multi-channel structure using a multi-layer gate. The GAA-type MOS transistor includes a multi-layer gate that is surrounded by a channel region. Accordingly, an extended channel having a bridge shape is formed about the circumference of the multi-layer gate electrode. In this manner, the GAA-type MOS transistor has a greater effective channel length or width than the fin type and the DELTA type transistor. The GAA structure is disclosed in U.S. Pat. No. 6,605,847.

A method of manufacturing a conventional MOS transistor with a GAA structure will now be described in further detail.

Referring to FIG. 1A, a first material layer 15 and a second material layer 20 are alternately stacked on a semiconductor substrate 10 to form a stacked structure 25. The first material layer 15 provides a location for a gate electrode and may comprise a silicon-germanium layer. The second material layer 20 functions as a channel region and may comprise a silicon layer.

Next, an active mask (not shown) is formed on a portion of the top of the stacked structure 25. The active mask is comprised of a pad oxide layer and a silicon nitride layer. Then, a trench is formed by etching the stacked structure 25 according to the shape of the active mask. As illustrated in FIG. 1B, an isolation layer 30 is formed by filling an insulator material in the trench. The active mask is removed by a conventional method. When removing the active mask, the pad oxide (not shown) film can remain on the surface of the resultant substrate 10.

An etch stopper 35, which is formed of a silicon nitride film, is deposited on the entire top surface of the semiconductor substrate 10 with the isolation layer 30 as illustrated in FIG. 1C, a dummy gate layer 40 is formed on the etch stopper 35 and patterned to the shape of the gate electrode, and then the etch stopper 35 and the stacked structure 25 are etched using the dummy gate layer 40 as a mask.

As illustrated in FIG. 1D, source and drain regions 45a and 45b are formed using an epitaxial growth process on the semiconductor substrate 10, which is exposed by etching the stacked structure 25. Later, a silicon nitride film 50 is formed to fill a space between the dummy gate layers 40.

Referring to FIG. 1E, the dummy gate layer 40 is selectively removed, and then the etch stopper 35 is removed to expose the surface of the stacked structure 25 and the surface of the isolation layer 30. Next, the isolation layer 30 is etched using the silicon nitride film 50 as a mask, thereby forming a recess 55 in the isolation layer 30. At this point, the sidewall of the stacked structure is exposed by the recess 55.

As illustrated in FIG. 1F, the first material layer 15 is removed through the exposed sidewall of the stacked structure 25, thereby forming a plurality of tunnels in the stacked structure 25. Next, after removing the pad oxide (not shown) film from the surface of the second material layer 20, a gate insulation film 60 is formed on the exposed surface of the second material layer 20 and the surface of the semiconductor substrate 10. Thereafter, a gate electrode 65 is formed by filling the recess region 55 and the tunnel. A similar method of manufacturing the GAA-type MOS transistor is disclosed in Japanese Patent Publication No. 2005-79517.

In a method of manufacturing the conventional GAA type MOS transistor, a surface of a surface of the stacked structure 25 is exposed to the external environment during a process of forming the recess 55 on the isolation layer 30 and during a process of removing the first material layer 15 to form a plurality of tunnels.

Thus, the second material layer 20 on the top of the stacked structure 25 can become damaged or partially lost when exposed to the etching media (e.g. etching gas). Although, the first material layer 15 and the second material layer 20 have different etching selectivities, the first and second material layers 15 and 20 can be affected by each other's etching gas. Thus, since the second material layer 20 on the top of the stacked structure 25 is exposed, the second material layer 20 is affected by the etching gas used for the first material layer 15 during a process of selectively removing the first material layer 15. In addition, although the isolation layer 30 of the silicon oxide film and the second material layer 20 of the silicon film have different etching selectivities, the exposed second material layer 20 can also become damaged by the etching gas used to etch the isolation layer 30 for a long time to form such a deep recess.

Therefore, the second material layer 20 on the top of the stacked structure 25 is more frequently damaged by the etching gas than the other layers. Especially, since the second material layer 20 functions as a channel region in the GAA-type MOS transistor, the mobility characteristics and overall operational characteristics of the MOS transistor are degraded due to damage or non-uniformity of the second material layer 20.

FIG. 2 is a transmission electron microscope (TEM) view illustrating a channel region of a conventional MOS transistor with a GAA structure. Referring to FIG. 2, the top second material layer 20 has a non-uniform thickness as compared with the lower second material layer 20, due to the damage caused by the etching gas.

### SUMMARY OF THE INVENTION

The present invention provides a method of manufacturing a MOS transistor with a multi-channel in manner that prevents damage and loss of material of a channel region.

In one aspect, the present invention is directed to a method of manufacturing a MOS transistor with a multiple channel structure, the method comprising: forming a stacked structure including a plurality of first material layers and a plurality of second material layers that have different etching selectivities and are alternately stacked on a semiconductor substrate; forming an active mask on a portion of the stacked structure, the active mask defining an active region; etching regions of the stacked structure to expose sidewalls of the stacked structure; forming a plurality of tunnels by selectively removing the first material layer between the exposed sidewalls of the stacked structure; removing the active mask; and forming a gate electrode on the active region to fill the plurality of tunnels.

In one embodiment, the first material layer is formed of a material having etching selectivity with respect to the semiconductor substrate.

In another embodiment, the second material layer is formed of a single crystal semiconductor layer.

In another embodiment, the first material layer is formed of a silicon germanium layer and the second material layer is formed of a silicon layer and wherein the semiconductor substrate is one of a silicon substrate and an SOI (silicon on insulator) substrate.

In another embodiment, forming the active mask includes: forming a pad oxide film on the semiconductor substrate; forming a silicon nitride film on the pad oxide film; and patterning a portion of the silicon nitride film and the pad oxide film.

In another embodiment, the pad oxide film is formed to a thickness of 200-300 Å and the silicon nitride film is formed to a thickness of 850-1200 Å

In another embodiment, forming the active mask further comprises: etching a portion of the stacked structure and the semiconductor substrate using the active mask as an etch mask; forming an insulation film on the semiconductor substrate to fill a space between the active masks; and forming an isolation layer by planarizing the insulation film and the active mask.

In another embodiment, the insulation film and the active mask are planarized such that the silicon nitride film of the active mask has a thickness of about 200-300 Å.

In another embodiment, etching regions of the stacked structure includes: forming a dummy gate pattern on a portion of the active mask; patterning the active mask using the dummy gate pattern as a mask; and exposing the semiconductor substrate by etching the stacked structure exposed using the dummy gate pattern and the active mask.

In another embodiment, the method further comprises forming source and drain regions in the active region.

In another embodiment, forming the source and drain regions includes: forming an epitaxial growth layer by performing an epitaxial growth process on the exposed semiconductor substrate; and implanting a dopant into the epitaxial growth layer.

In another embodiment, the forming of the dummy gate pattern includes: forming a dummy gate layer on the active mask; forming a hard mask film on the dummy gate layer; forming a photoresist pattern on the hard mask film; and patterning the hard mask film and the dummy gate layer using the photoresist pattern as a patterning mask.

In another embodiment, the dummy gate pattern is a silicon oxide film.

In another embodiment, exposing the sidewalls of the stacked structure includes: forming a silicon nitride film on the semiconductor substrate including the dummy gate pattern; selectively removing the dummy gate pattern; and etching the isolation layer using the silicon nitride film as an etch mask.

In another embodiment, forming the gate electrode includes: forming a gate insulation film on a top surface of the semiconductor substrate, an inner surface of the plurality of tunnels, and on a top surface of the second material layer; depositing a conductive layer on the semiconductor substrate that fills the plurality of tunnels and the recess; and planarizing the conductive layer to expose the silicon nitride film.

In another aspect, the present invention is directed to a method of manufacturing a MOS transistor with a multiple channel structure, the method comprising: forming a stacked structure on a semiconductor substrate including a plurality of sacrificial gate layers and a plurality of channel layers that are alternately stacked; forming an active mask on a portion of a top of the stacked structure; defining an active region by etching the stacked structure using the active mask as an etch mask; forming an isolation layer in a space between the active regions; forming source and drain regions in a portion of the active region; forming a recess in the isolation layer to expose a sidewall of the stacked structure, with the active mask present to cover the stacked structure during formation of the recess; forming a plurality of tunnels by selectively removing the sacrificial gate layer through the exposed sidewall of the stacked structure; removing the active mask; and forming a gate electrode on the active region by filling the plurality of tunnels.

In one embodiment, the sacrificial gate layer and the channel layer are single crystal semiconductor layers having different etching selectivities.

In another embodiment, the sacrificial gate layer is formed of a silicon germanium layer and the channel layer is formed of a silicon layer when the semiconductor substrate is one of a silicon substrate and an SOI substrate.

In another embodiment, forming the isolation layer includes: depositing a insulation film to fill a space between the active regions; and planarizing the insulation film and the active mask to form the active mask.

In another embodiment, forming the source and drain regions includes: forming a dummy gate pattern on a portion of the active mask; patterning the active mask in the dummy gate pattern; exposing the semiconductor substrate by etching the stacked structure exposed using the dummy gate pattern and the active mask; forming an epitaxial growth layer by performing an epitaxial growth process on the exposed semiconductor substrate; and implanting a dopant into the epitaxial growth layer.

In another embodiment, forming the recess in the isolation layer includes: forming a silicon nitride film on the semiconductor substrate including the dummy gate pattern; selectively removing the dummy gate pattern; and etching the isolation layer using the silicon nitride film as a mask.

In another embodiment, forming the gate electrode includes: forming a gate insulation film on a top surface of the semiconductor substrate, an inner surface of the plurality of tunnels, and the top surface of a second material layer; depositing a conductive layer on the semiconductor substrate that fills the plurality of tunnels and the recess; and planarizing the conductive layer to expose the silicon nitride film.

According to embodiments of the present invention, since the active mask defining the active region is present during formation of the plurality of tunnels and is later removed following their formation, the channel layer, or the second material layer, is protected from the etching process, and is therefore not subject to damage and/or material removal as a result of the etching process.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1F are sectional views illustrating a method of manufacturing a conventional MOS transistor with a multi-channel;

FIG. 2 is a TEM view illustrating a channel region when manufacturing a conventional MOS transistor with a GAA structure;

FIGS. 3A through 3H are sectional views illustrating a method of manufacturing a MOS transistor with a multi-channel according to an embodiment of the present invention; and

FIG. 4 is a plan view of a MOS transistor according to an embodiment of the present invention.

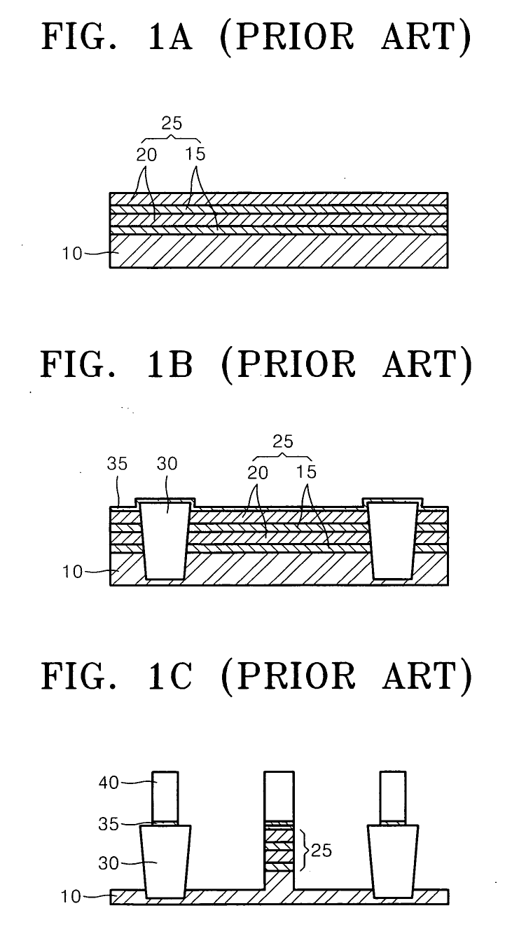

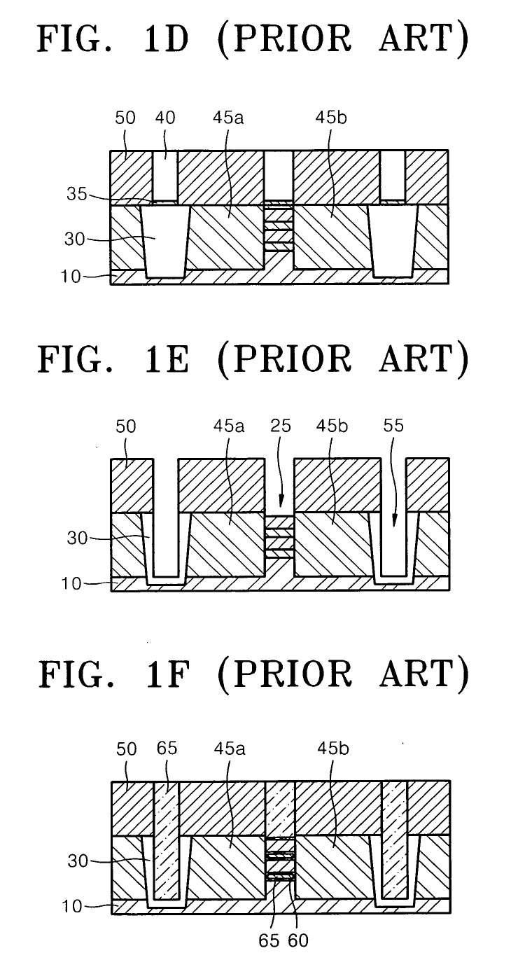

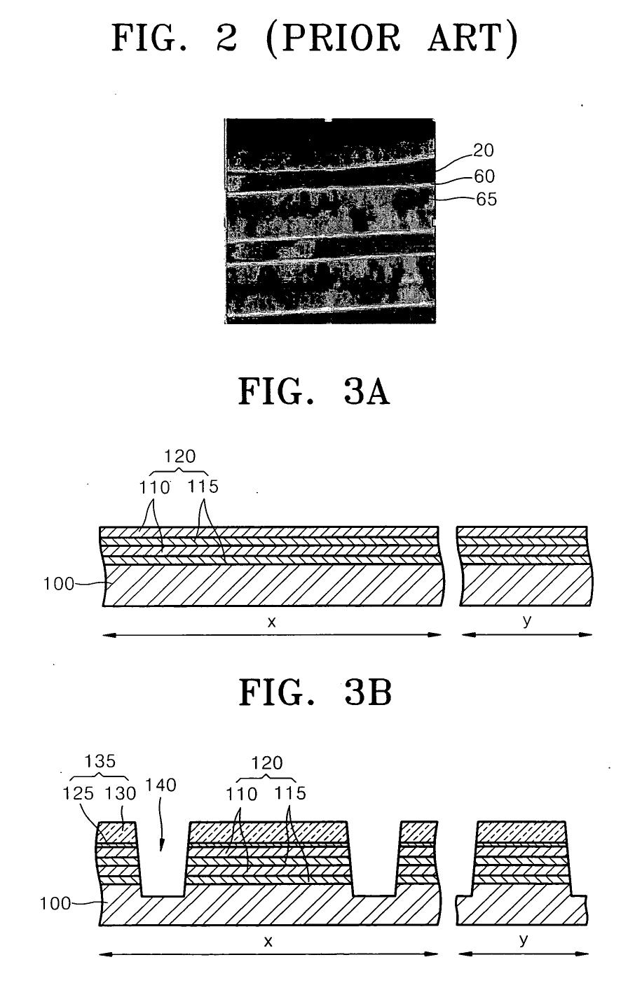

### DETAILED DESCRIPTION OF EMBODIMENTS OF THE INVENTION

The present invention will now be described more fully with reference to the accompanying drawings, in which exemplary embodiments of the invention are shown. The invention may, however, be embodied in many different forms, and should not be construed as being limited to the embodiments set forth herein; rather, these embodiments are provided so that this disclosure will be thorough and complete. Like reference numerals denote like elements in the drawings, and thus their description will not be repeated.

In the present invention, an active mask for defining an active region (or an isolation layer) is removed after a plurality of gate tunnels are formed. In this manner, damage and loss of an uppermost channel region of the multi-channel structure will be prevented. Since this active mask is formed on the channel region and functions as an etch stopper, an additional etch stopper is unnecessary.

In an embodiment of the present invention, a method of manufacturing a MOS transistor with a multi-channel, which protects a top channel by removing the active mask after a gate tunnel is formed, will now be described with reference to the drawings.

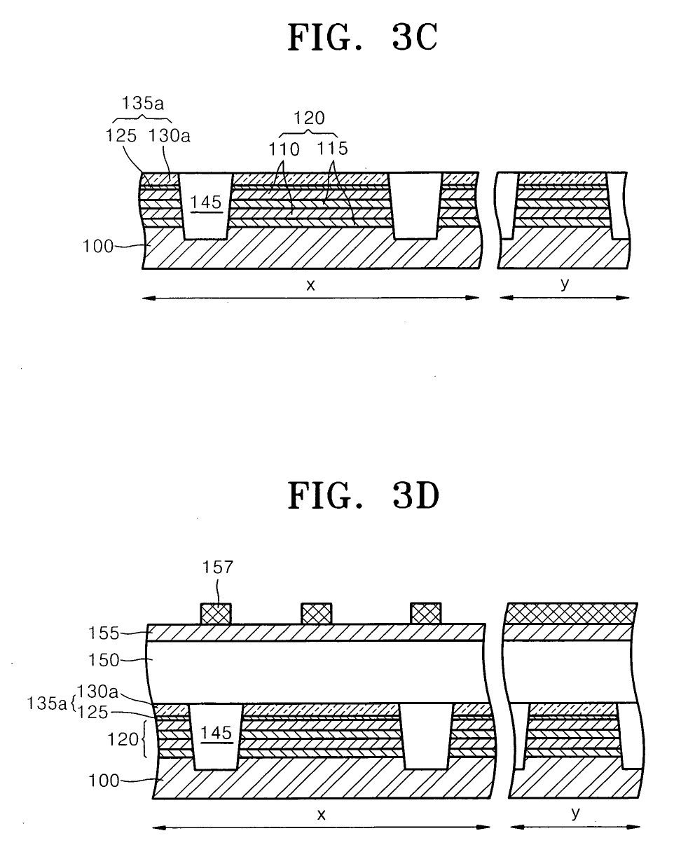

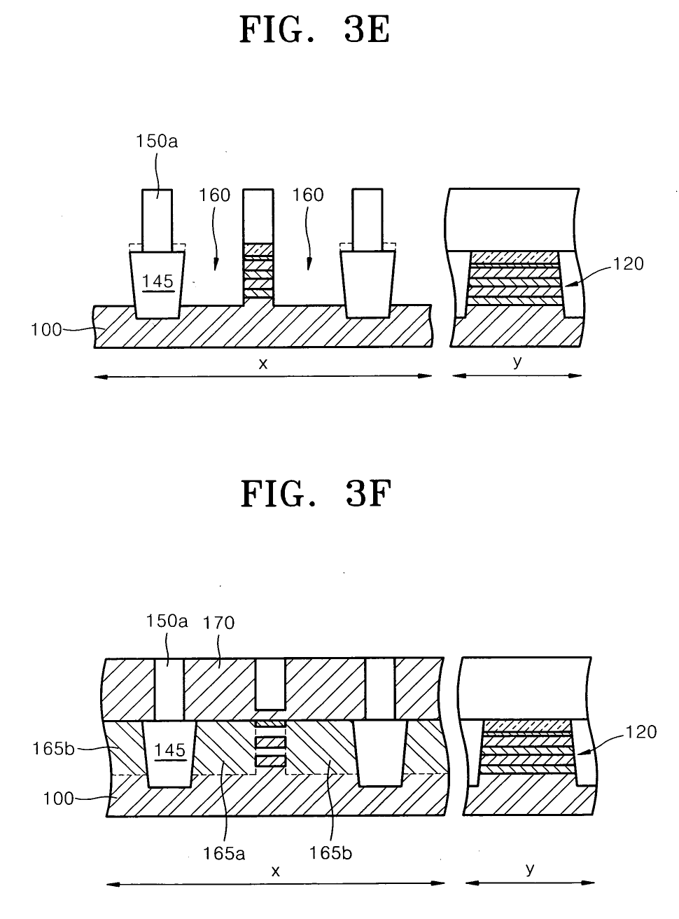

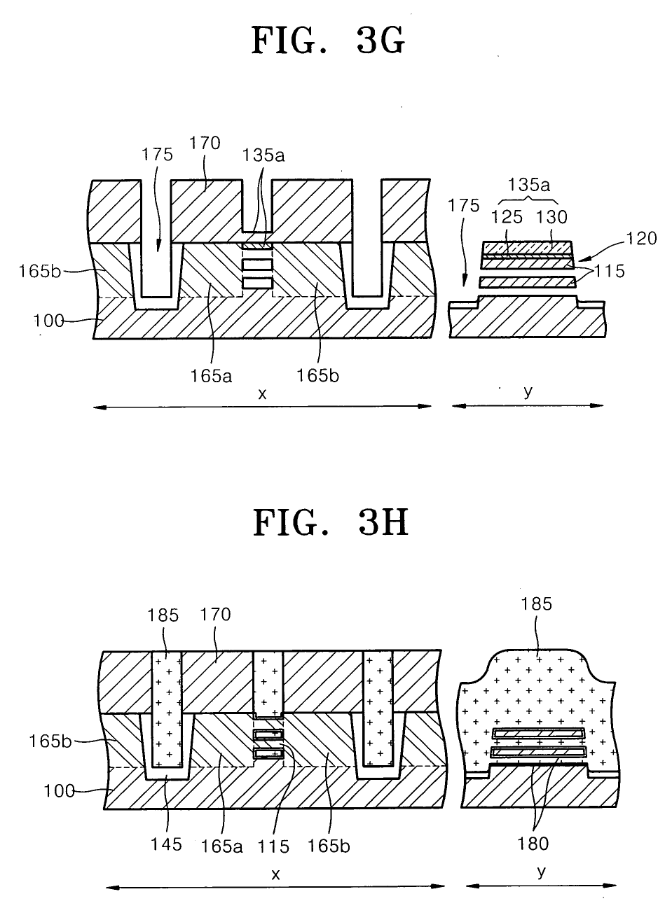

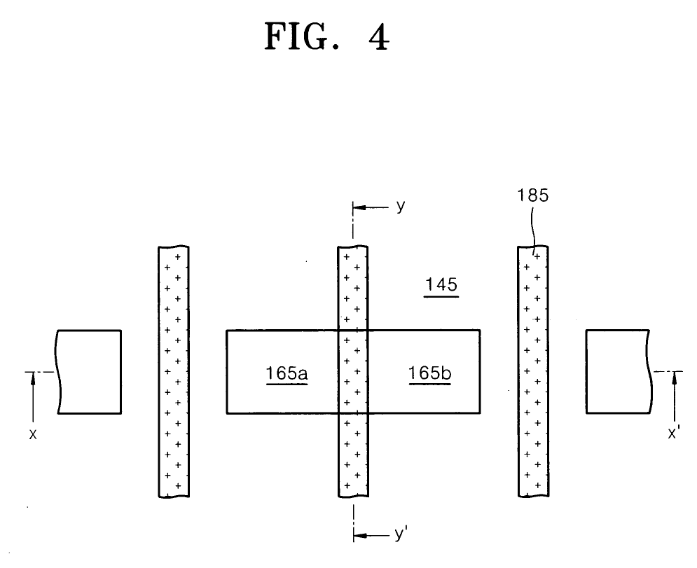

FIGS. 3A through 3H are sectional views illustrating a method of manufacturing the MOS transistor with a multi-channel according to an embodiment of the present invention. FIG. 4 is a plan view of the MOS transistor according to an embodiment of the present invention. The portion X of FIGS. 3A through 3H is a sectional view taken along section line x-x′ of FIG. 4 and intersects a gate electrode. The portion Y of FIGS. 3A through 3H is a sectional view taken along section line y-y′ of FIG. 4 and is parallel to the gate electrode.

First, as illustrated in FIG. 3A, a semiconductor substrate 100 is prepared. The semiconductor substrate 100 may be a bulk silicon (bulk Si) substrate, a silicon germanium (SiGe) substrate, a silicon on insulator (SOI) substrate, or a SiGe on insulator (SGOI) substrate. A plurality of first material layers 110 and a plurality of second material layers 115 are stacked alternately to form a stacked structure 120. It is desirable that the first material layer 110 and the second material layer 115 are alternately stacked more than two times. The first and second material layers 110 and 115 are formed, for example, using an epitaxial growth process. The first material layer (a sacrificial gate layer) 110 is provided to form a location in which a gate electrode will later be formed. The second material layer (a channel layer) 115 is provided to form a channel of the MOS transistor. The first and second material layers 110 and 115 may be single crystal semiconductor layers having a predetermined etching selectivity under given etching conditions. For example, the first material layer 110 may be a silicon germanium layer when the semiconductor substrate 100 is a silicon substrate or a SOI substrate. Alternatively, the first material layer 110 may be a silicon layer when the semiconductor substrate 100 is a silicon germanium substrate or a SGOI substrate. Furthermore, the second material layer 115 may be formed of the same material as the semiconductor substrate 100. In one embodiment each of the first material layers 110 is formed to a thickness of 20-30 nm, and each of the second material layers 115 is formed to a thickness of 10-20 nm.

Next, as illustrated in FIG. 3B a pad oxide film 125 is formed on the stacked structure 120 to a thickness of 200-300 Å, and a silicon nitride film 130 is formed on the pad oxide film 125 to a thickness of 850-1200 Å. The silicon nitride film 130 and the pad oxidation layer 125 are patterned to expose a region of the isolation layer to be formed to form an active mask 135. A trench 140 is formed by etching a portion of the stacked structure 120 and the semiconductor substrate 100 using the active mask 135.

Referring to FIG. 3C, an insulation film is deposited on the semiconductor substrate 100 to fill the trench 140. Next, a shallow trench isolation (STI) layer 145 is formed by planarizing the insulation film and the active mask 135a using a CMP (Chemical Mechanical Polishing) process. For example, the insulation film and the active mask 135a are planarized such that the thickness of the silicon nitride film of the active mask 135a becomes in the range of 300-500 Å.

As illustrated in FIG. 3D, without removing the active mask 135a, a dummy gate layer 150 and a hard mask film 155 are sequentially formed on the active mask 135a and the STI layer 145. The dummy gate layer 150 may be formed of the silicon oxide layer and the hard mask film 155 may be formed of the silicon nitride film. A photoresist pattern 157 is formed to define a gate electrode on the hard mask film 155 using a conventional photolithography process.

Referring to FIG. 3E, the hard mask film 155 is patterned using the photoresist pattern 157 as a mask. The photoresist pattern 157 is then removed. Next, a dummy gate pattern 150a is formed by etching the dummy gate layer 150 using the patterned hard mask film 155 as a mask. The dummy gate layer 150 is etched until the surface of the silicon nitride film 130a of the active mask 135a is exposed. Then, the exposed hard mask film 155 and the active mask 135a are removed using the dummy gate pattern 150a as a mask. At this point, the STI layer 145 can be partially lost due to the absence of the etch stopper between the dummy gate pattern 150a and the STI film 145 during a process of etching the dummy gate pattern 150a and a process of removing the pad oxide film 125 of the active mask 135a. However, since the active mask 135a remains when forming the STI layer 145 and the STI layer 145 is formed relatively thick. Consequently, it is thereby possible to compensate for the loss of thickness of the STI layer 145 during a process of removing the dummy gate pattern 150a and the pad oxide film 125, because of the relative thickness of the active mask 135a that is present during the formation of the STI layer 145

Spaces 160 for source and drain regions are then formed by etching the exposed stacked structure 120 using the remaining dummy gate pattern 150a and the STI layer 145 as a mask.

As illustrated in FIG. 3F, an epitaxial film is formed in a space where the source and drain regions will be formed, by performing an epitaxial growth process on the exposed semiconductor substrate 100 and the exposed stacked structure 120. Next, the source and drain regions 165a and 165b are formed by doping the epitaxial layer with a dopant of a conductivity type opposite to that of the semiconductor substrate 100. A dopant region (not shown) having a type opposite to that of the source and drain regions 165a and 165b may be further formed on the semiconductor substrate 100 region between the source and drain regions 165a and 165b to provide a channel stop.

Next, a silicon nitride film 170 is deposited on the semiconductor substrate 100 to fill the space between the dummy gate patterns 150a. Then, the silicon nitride film 170 is polished, for example using chemical-mechanical polishing (CMP), to expose the dummy gate pattern 150a.

Next, as illustrated in FIG. 3G, the dummy gate pattern 150a between the silicon nitride films 170 is selectively removed by dry etching process and wet etching process. Then, a recess 175 in the STI layer 145 is formed by etching the STI layer 145 using the silicon nitride film 170 as a mask. A sidewall of the stacked structure 120 is exposed by the recess 175 in the STI layer 145 (see portion Y of FIG. 3G). Since there is no etch stopper present between the STI layer 145 and the dummy gate pattern 150a, the dummy gate pattern 150a is removed to form the recess 175a with only one process. At this point, the second material layer 115 at the top of the stacked structure 120 is protected by the remaining portion of the active mask 135a from etching media (e.g. etching gas) during the process of removing the dummy gate pattern 150a and during the process of forming the recess 175 in the STI layer 145.

The first material layer 110 is then selectively removed through the sidewall of the exposed stacked structure 120, thereby forming a plurality of tunnels between the second material layers 115. The first material layer 110 can be removed, for example, by dry etching or wet etching. Also, the stacked structure 120 is covered by the active mask 135a, and thus is not affected by the etching media during removal of the first material layer.

As illustrated in FIGS. 3H and 4, the remaining active mask 135a is removed by conventional removal processes. Since the pad oxide film and the silicon nitride film constituting the active mask 135a have excellent etching selectivity characteristics, the active mask 135a can be selectively removed without damaging the second material layer 115 of the stacked structure.

Then, a gate insulation film 180 is formed on the exposed surface of the second material layer 114, the inner surface of the tunnel, and the surface of the semiconductor substrate. The gate insulation film 180 is formed by thermal oxidation. Next, a conductive layer is deposited on the semiconductor substrate 100 to fill the recess 175 and the plurality of tunnels. Then, a gate electrode 185 is formed by planarizing the conductive layer such that the silicon nitride film 170 is exposed.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A method of manufacturing a MOS transistor with a multiple channel structure, the method comprising:
forming a stacked structure including a plurality of first material layers and a plurality of second material layers that have different etching selectivities and are alternately stacked on a semiconductor substrate;
forming an active mask on a portion of the stacked structure, the active mask defining an active region;
etching regions of the stacked structure to expose sidewalls of the stacked structure;
forming a plurality of tunnels by selectively removing the first material layer between the exposed sidewalls of the stacked structure;
removing the active mask; and
forming a gate electrode on the active region to fill the plurality of tunnels.

2. The method of claim 1, wherein the first material layer is formed of a material having etching selectivity with respect to the semiconductor substrate.

3. The method of claim 1, wherein the second material layer is formed of a single crystal semiconductor layer.

4. The method of claim 1, wherein the first material layer is formed of a silicon germanium layer and the second material layer is formed of a silicon layer and wherein the semiconductor substrate is one of a silicon substrate and an SOI (silicon on insulator) substrate.

5. The method of claim 1, wherein forming the active mask includes:
forming a pad oxide film on the semiconductor substrate;
forming a silicon nitride film on the pad oxide film; and
patterning a portion of the silicon nitride film and the pad oxide film.

6. The method of claim 5, wherein the pad oxide film is formed to a thickness of 200-300 Å and the silicon nitride film is formed to a thickness of 850-1200 Å

7. The method of claim 6, wherein forming the active mask further comprises:
etching a portion of the stacked structure and the semiconductor substrate using the active mask as an etch mask;
forming an insulation film on the semiconductor substrate to fill a space between the active masks; and
forming an isolation layer by planarizing the insulation film and the active mask.

8. The method of claim 7, wherein the insulation film and the active mask are planarized such that the silicon nitride film of the active mask has a thickness of about 200-300 Å.

10. The method of claim 7, wherein etching regions of the stacked structure includes:
forming a dummy gate pattern on a portion of the active mask;
patterning the active mask using the dummy gate pattern as a mask; and
exposing the semiconductor substrate by etching the stacked structure exposed using the dummy gate pattern and the active mask.

11. The method of claim 7, further comprising forming source and drain regions in the active region.

12. The method of claim 11, wherein forming the source and drain regions includes:
forming an epitaxial growth layer by performing an epitaxial growth process on the exposed semiconductor substrate; and
implanting a dopant into the epitaxial growth layer.

13. The method of claim 12, wherein the forming of the dummy gate pattern includes:
forming a dummy gate layer on the active mask;
forming a hard mask film on the dummy gate layer;
forming a photoresist pattern on the hard mask film; and
patterning the hard mask film and the dummy gate layer using the photoresist patter as a patterning mask.

14. The method of claim 12, wherein the dummy gate pattern is a silicon oxide film.

15. The method of claim 10, wherein exposing the sidewalls of the stacked structure includes:
forming a silicon nitride film on the semiconductor substrate including the dummy gate pattern;
selectively removing the dummy gate pattern; and
etching the isolation layer using the silicon nitride film as an etch mask.

16. The method of claim 1, wherein forming the gate electrode includes:
forming a gate insulation film on a top surface of the semiconductor substrate, an inner surface of the plurality of tunnels, and on a top surface of the second material layer;
depositing a conductive layer on the semiconductor substrate that fills the plurality of tunnels and the recess; and
planarizing the conductive layer to expose the silicon nitride film.

17. A method of manufacturing a MOS transistor with a multiple channel structure, the method comprising:
forming a stacked structure on a semiconductor substrate including a plurality of sacrificial gate layers and a plurality of channel layers that are alternately stacked;
forming an active mask on a portion of a top of the stacked structure;
defining an active region by etching the stacked structure using the active mask as an etch mask;
forming an isolation layer in a space between the active regions;
forming source and drain regions in a portion of the active region;
forming a recess in the isolation layer to expose a sidewall of the stacked structure, with the active mask present to cover the stacked structure during formation of the recess;
forming a plurality of tunnels by selectively removing the sacrificial gate layer through the exposed sidewall of the stacked structure;
removing the active mask; and
forming a gate electrode on the active region by filling the plurality of tunnels.

18. The method of claim 17, wherein the sacrificial gate layer and the channel layer are single crystal semiconductor layers having different etching selectivities.

19. The method of claim 17, wherein the sacrificial gate layer is formed of a silicon germanium layer and the channel layer is formed of a silicon layer when the semiconductor substrate is one of a silicon substrate and an SOI substrate.

20. The method of claim 17, wherein forming the isolation layer includes:
depositing a insulation film to fill a space between the active regions; and
planarizing the insulation film and the active mask to form the active mask.

21. The method of claim 17, wherein forming the source and drain regions includes:
forming a dummy gate pattern on a portion of the active mask;
patterning the active mask in the dummy gate pattern;
exposing the semiconductor substrate by etching the stacked structure exposed using the dummy gate pattern and the active mask;
forming an epitaxial growth layer by performing an epitaxial growth process on the exposed semiconductor substrate; and
implanting a dopant into the epitaxial growth layer.

22. The method of claim 21, wherein forming the recess in the isolation layer includes:
forming a silicon nitride film on the semiconductor substrate including the dummy gate pattern;
selectively removing the dummy gate pattern; and
etching the isolation layer using the silicon nitride film as a mask.

23. The method of claim 17, wherein forming the gate electrode includes:
forming a gate insulation film on a top surface of the semiconductor substrate, an inner surface of the plurality of tunnels, and the top surface of a second material layer;
depositing a conductive layer on the semiconductor substrate that fills the plurality of tunnels and the recess; and
planarizing the conductive layer to expose the silicon nitride film.
